(19) United States
(12) Patent Application Publication
(10) Pub. No.: US 2016/0284639 A1
(43) Pub. Date: Sep. 29, 2016

(54) SEMICONDUCTOR STRUCTURE

(71) Applicants: CHIPMOS TECHNOLOGIES INC, Hsinchu (TW); CHIPMOS TECHNOLOGIES (BERMUDA) LTD., Hamilton (BM)

(72) Inventor: SHENG-PAI CHEN, HSINCHU (TW)

(21) Appl. No.: 14/856,469

(22) Filed: Sep. 16, 2015

(30) Foreign Application Priority Data
Mar. 27, 2015 (TW) 104109922

(51) Int. Cl. H01L 23/528; H01L 23/00

(52) U.S. Cl. CPC H01L 23/528; H01L 24/05; H01L 2224/0401; H01L 2224/0502

(57) ABSTRACT

The present disclosure relates to a semiconductor structure, which includes a semiconductor substrate, an insulating layer and a plurality of wirings. The insulating layer is disposed on the semiconductor substrate. The plurality of wirings are disposed between the semiconductor substrate and the insulating layer. At least one wiring of the wirings includes a plurality of holes, and a total area of the holes is from 10% to 70% of a surface area of the at least one wiring.

### BACKGROUND

The present disclosure relates to a semiconductor structure, and more particularly to, a semiconductor structure having wirings with a plurality of holes.

In wafer level packaging (WLP), the front-end process is wafer bumping. The bumping mainly includes the formation of under bump metallurgy (UBM) and solder bumps. In an advanced process of under bump metallurgy, the redistribution technology is introduced to adjust input/output locations of components so as to improve structure stability of the components. In the process of forming the redistribution layer, poor adhesion between wirings made of plating metal such as copper and the coated polymer dielectric layer easily results in delamination between the polymer dielectric layer and the wirings, leading to product failure during the long term reliability test. In addition, during a thermal cycling test (TCT), due to the difference between the coefficients of thermal expansion (CTE) of different materials, thermal stresses easily accumulate on an interface between the materials leading to the generation of delamination and further resulting in cracks, which will affect functions and life of the products.

Accordingly, a novel design is needed to improve the above problems in this field.

### BRIEF SUMMARY OF THE INVENTION

One of the objectives of the present disclosure is to provide semiconductor structures characterized by wirings with a plurality of holes.

According to a first aspect of the present disclosure, a semiconductor structure is disclosed. The semiconductor structure includes a semiconductor substrate, an insulating layer disposed on the semiconductor substrate, and a plurality of wirings disposed between the semiconductor substrate and the insulating layer, wherein at least one wiring of the wirings includes a plurality of holes, and a total area of the holes is from 10% to 70% of a surface area of the at least one wiring.

According to a second aspect of the present disclosure, a semiconductor structure is disclosed. The semiconductor structure includes a semiconductor substrate; a dielectric layer disposed on the semiconductor substrate, a plurality of wirings disposed on the dielectric layer, wherein at least one wiring of the wirings includes a plurality of holes, and an insulating layer disposed on the semiconductor substrate and partially covering the wirings, wherein a part of the insulating layer is disposed in the holes and contacts the dielectric layer through the holes, wherein a total area of the holes is from 10% to 70% of a surface area of the at least one wiring.

### BRIEF DESCRIPTION OF THE DRAWINGS

FIG. 1 is a cross sectional view of a semiconductor structure according to a first embodiment of the present invention;

FIG. 2 shows a top view of the semiconductor structure in FIG. 1;

FIG. 3A shows a top view of a semiconductor structure according to a second embodiment of the present invention;

FIG. 3B shows a top view of a semiconductor structure according to a third embodiment of the present invention;

FIG. 4 shows a top view of a semiconductor structure according to a fourth embodiment of the present invention;

FIG. 5A show a top view of a semiconductor structure according to a fifth embodiment of the present invention;

FIG. 5B show a top view of a semiconductor structure according to a sixth embodiment of the present invention; and

FIG. 5C show a top view of a semiconductor structure according to a seventh embodiment of the present invention.

### DETAILED DESCRIPTION

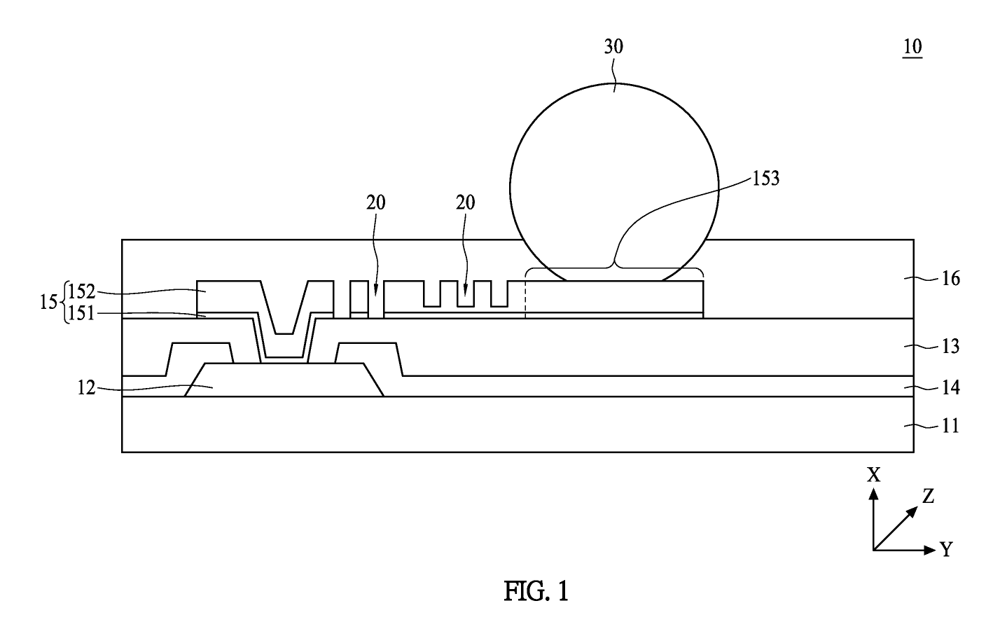

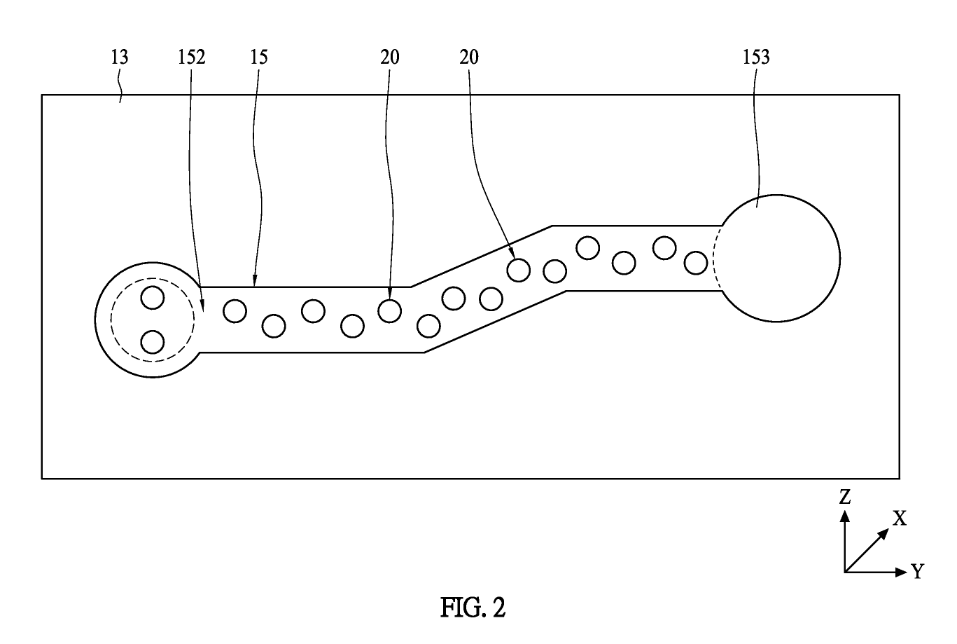

FIG. 1 is a cross sectional view of a semiconductor structure according to an embodiment of the present invention. To facilitate the description of features of the present invention, FIG. 2 to FIG. 5 are top views showing a semiconductor structure according to some embodiments of the present invention, wherein an insulating layer and a bump are omitted. As shown in FIG. 1, a semiconductor structure 10 is provided, and the semiconductor structure 10 includes a semiconductor substrate 11, a metal pad 12, a dielectric layer 13, a protection layer 14, a plurality of wirings 15 and an insulating layer 16. The metal pad 12 is formed on the semiconductor substrate 11. The metal pad 12 can be, for example, an input/output (I/O) pad of an integrated circuit on a semiconductor wafer, and the material of the metal pad can include aluminum, copper or other suitable materials. The protection layer 14 is disposed on the semiconductor substrate 11, and has an opening partially exposing the metal pad 12. In other words, a part of the metal pad 12 is covered by the protection layer 14, and the remaining part of the metal pad 12 is exposed by the opening of the protection layer 14. The protection layer 14 is an electrically insulating surface layer disposed on the semiconductor substrate 11, or called passivation layer. The material of the protection layer 14 can be silicon oxide, silicon nitride, nitride, polyimide (PI), benzocyclobutene (BCB), phosphosilicate glass, etc. The protection layer 14 can be formed by chemical vapor deposition (CVD) for protecting the integrated circuits including the metal pad 12 on the semiconductor substrate 11. The dielectric layer 13 is disposed on the protection layer 14, and has an opening corresponding to the opening of the protection layer 14 such that the metal pad 12 is also partially exposed by the opening of the dielectric layer 13. The number of the metal pad 12 on the semiconductor substrate 11 is not limited in the present invention. In some embodiments, a plurality of metal pads 12 can be formed on the semiconductor substrate 11, and each of the metal pads 12 is corresponding to an opening of the protection layer and an opening of the dielectric layer. In this embodiment, the dielectric layer 13 extends into the opening of the protection layer 14. In other words, the opening of the dielectric layer 13 is smaller than the opening of the protection layer 14, and therefore the protection layer 14 is completely covered by the dielectric layer 13. However, in other embodiments, the opening of the dielectric layer 13 can be not smaller than the opening of the protection layer 14, such that the protection layer 14 is partially exposed by the dielectric layer. As shown in FIG. 1, the dielectric layer 13 is indirectly disposed on the semiconductor substrate 11 along X-axis.

A plurality of wirings 15 are disposed on the dielectric layer 13. In this embodiment, the wirings 15 include a seed layer 151 and a conductive layer 152, wherein the conductive layer 152 is formed on the seed layer 151. At least one of the wirings 15 fills into the openings of the dielectric layer 13 and the protection layer 14 to connect to the metal pad 12, and extends away from the metal pad 12 on the dielectric layer 13, which is so-called a redistribution layer (RDL). The redistribution layer is used for redistributing the metal pads 12 on the semiconductor substrate 11 to other positions in response to different requirements. Specifically, for example, the material of the wirings 15 is Ti/Cu, Ti/Cu/Au or Ti/Cu/Ni/Au. Taking Ti/Cu as an example, the wirings 15 are formed by first forming a seed layer 151 of Ti and Cu thin layers by sputtering, and then forming a conductive layer 152 with a certain thickness on the seed layer 151 by electroplating. Electrical signals hence can be transmitted by the wrings 15 from the metal pads 12 on the semiconductor substrate 11 to other components (not shown). As shown in FIG. 1, the wiring 15 further includes a contact pad 153 for a bump 30 to be disposed thereon. The bump 30 is disposed on the contact pad 153 so that the bump 30 is electrically connected to the metal pad 12 via the wiring 15. The bump 30 can be a solder bump, a electroplating bump, an electroless plating bump, a stud bump, a compliant bump or a metal composite bump, and the material of the bump 30 can be one selected from the group consisting of tin, copper, gold, silver, indium, nickel/gold, nickel/palladium/gold, copper/nickel/gold, copper/gold, aluminum, and an alloy thereof. In this embodiment, the bump 30 is a solder bump, and jointed to the contact pad 153 by a reflow process.

The insulating layer 16 is disposed on the dielectric layer 13, and the wirings 15 are partially covered by the insulating layer 16. Specifically, the insulating layer 16 has openings each partially exposing one of the contact pad 153 so as for the bump 30 to be disposed on the contact pad 153. As shown in FIG. 1, the insulating layer 16 is indirectly disposed on the semiconductor substrate 11 along x-axis. The material of the dielectric layer 13 and the insulating layer 16 can be selected from the group consisting of polyimide (PI), polybenzoxazole (PBO), benzocyclobutene (BCB) and an epoxy resin.

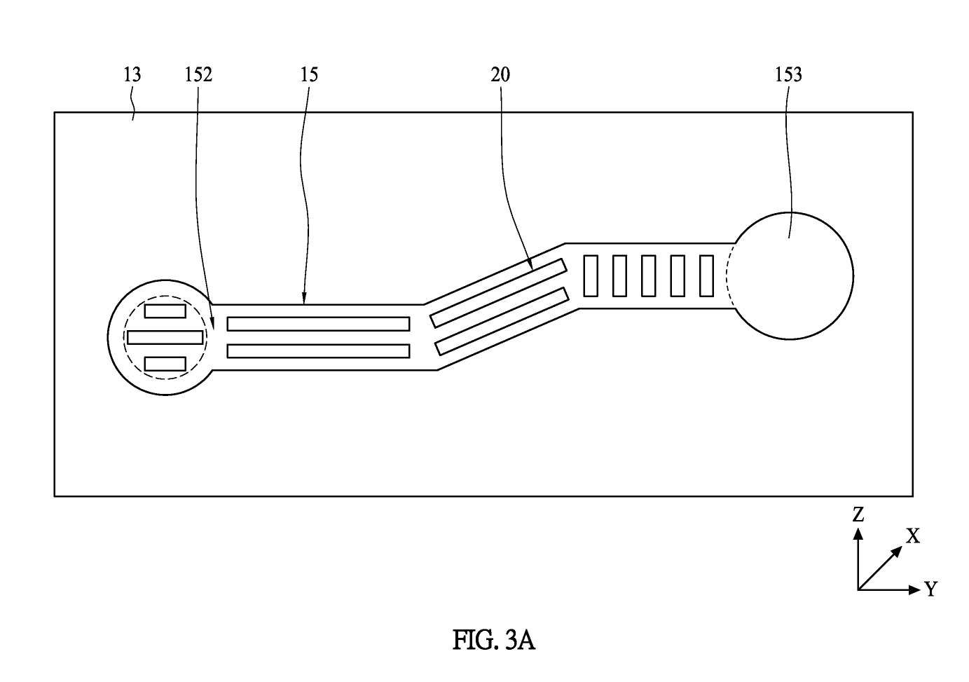

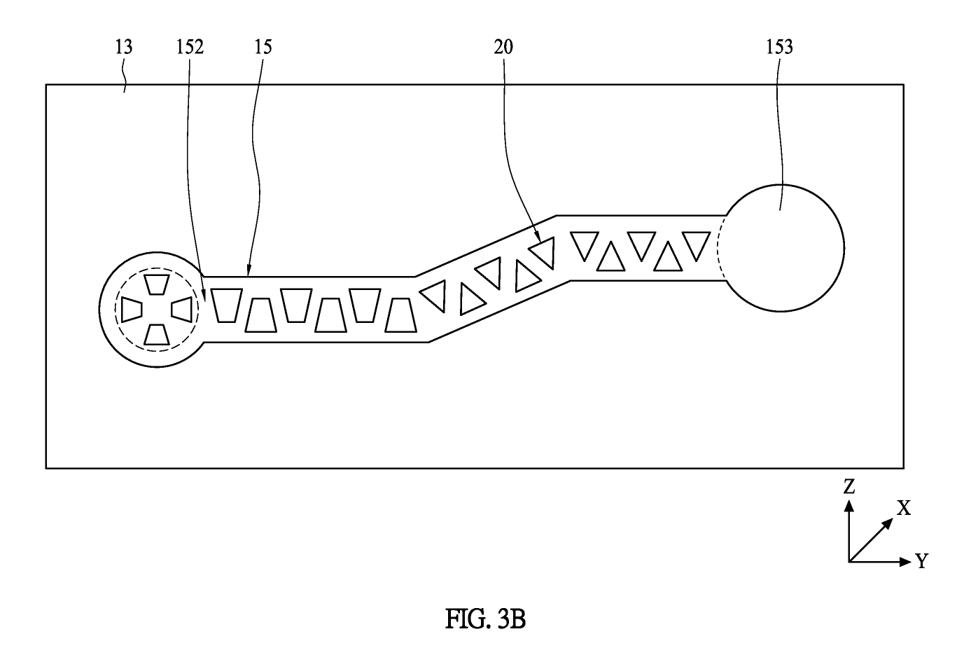

Referring to FIG. 1 and FIG. 2, FIG. 2 shows a top view of the semiconductor structure in FIG. 1. For simplicity, the bump 30 and the insulating layer 16 covering the dielectric layer 13 and the wirings 15 are not shown in FIG. 2. At least one wiring 15 of the wirings 15 includes a plurality of holes 20. The total aperture area of the holes 20 is from about 10% to about 70% of the surface area of the at least one wiring 15. The above percentage can be determined according to the difference between the coefficients of thermal expansion (CTE) of the wirings 15 and the insulating layer 16 or the dielectric layer 13. The quantity of metal of the at least one wiring 15 being reduced due to the formation of the holes 20 is determined such that the electrical transmission efficiency of the wiring 15 is not affected. The holes 20 increase the contact area between the insulating layer 16 and the wiring 15. The increase in the contact area improves the bonding strength between the wiring 15 and the insulating layer 16, so as to avoid delamination between the wiring 15 and the insulating layer 16. Specifically, when the insulating layer 16 partially covers the wiring 15, a part of the insulating layer 16 is filled in the holes 20. The holes can include blind holes without passing through the wiring 15 and/or through holes. When the holes 20 are through holes, the insulating layer 16 can contact the dielectric layer 13 via the holes 20. When the insulating layer 16 and the dielectric layer 13 are made of the same or similar material, the insulating layer 16 and the dielectric layer 13 can even connect as an integral via the holes 20 such that the bonding strength to the wiring 15 is further improved to avoid delamination. In addition, the wiring 15 is made of a metal material such as copper, which has a coefficient of thermal expansion of about 16-17 ppm/° C. , and insulating layer 16 and the dielectric layer 13 are made of polymer materials, such as polyimide, which have great variation in the coefficient of thermal expansion, for example, 80 ppm/° C. The difference between the coefficients of thermal expansion of the two different kinds of materials is huge, and the CTE mismatch results in the generation of thermal stresses between the two materials leading to delamination. In the present invention, the formation of the holes 20 in the wiring 15 reduces the quatity of metal of the wiring 15; since the percentage of metal is decreased, the degree of the CTE mismatch between the metal and the polymer is reduced so that the generation of the thermal mechanical stresses is lessened, and the delamination is avoided. FIG. 3A shows a top view of a semiconductor structure according to the second embodiment of the present invention, and FIG. 3B shows a top view of a semiconductor structure according to the third embodiment of the present invention. For simplicity, the bump 30 and the insulating layer 16 covering the dielectric layer 13 and the wiring 15 are not shown in FIG. 3A and FIG. 3B. As shown in FIG. 3A and FIG. 3B, in addition to the circular shape, the shape of the holes 20 can be, but not limited to, a strip, an oval, a triangle, a trapezoid, a comb, etc.

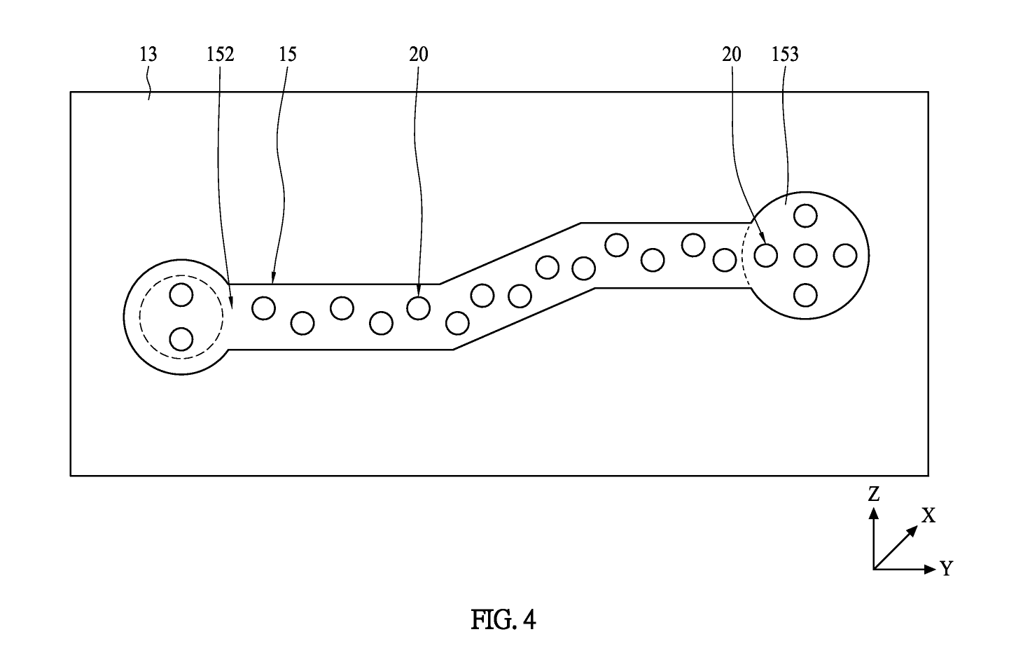

FIG. 4 shows a top view of a semiconductor structure according to the fourth embodiment of the present invention. For simplicity, the bump 30 and the insulating layer 16 covering the dielectric layer 13 and the wiring 15 are not shown in FIG. 4. As shown in FIG. 4, the holes 20 are not only formed on the main segment of the wiring 15, but also formed on the contact pad 153. Therefore, when the bump 30 is disposed on the contact pad 153, a part of the bump 30 can be filled in the holes 20. The contact area between the bump 30 and the contact pad 153 is increased by the holes 20, such that the bonding strength between the bump 30 and the contact pad 153 is enhanced avoiding the bump 30 from peeling off from the contact pad 153. Similarly, the holes 20 disposed at the contact pad 153 can also include blind holes without passing through the contact pad 153 and/or through holes. When the holes 20 are through holes, the bump 30 can contact the dielectric layer 13 via the holes 20.

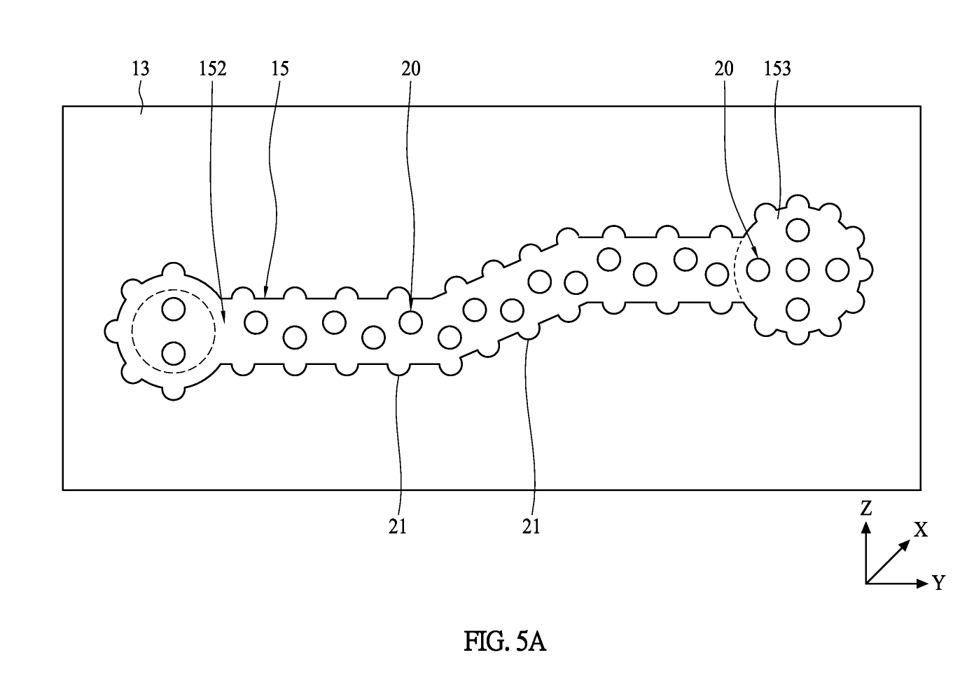

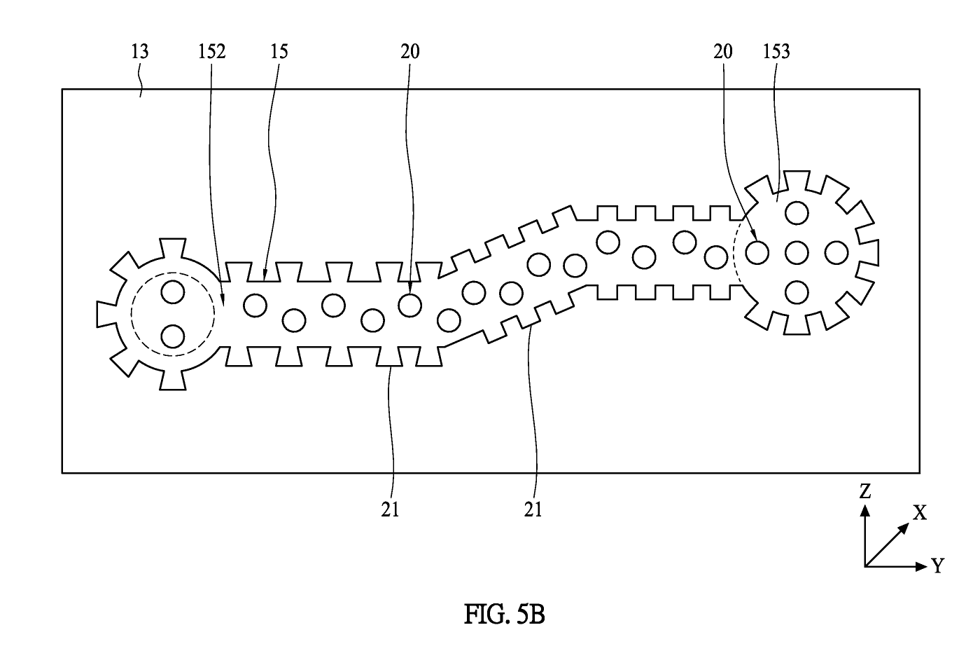

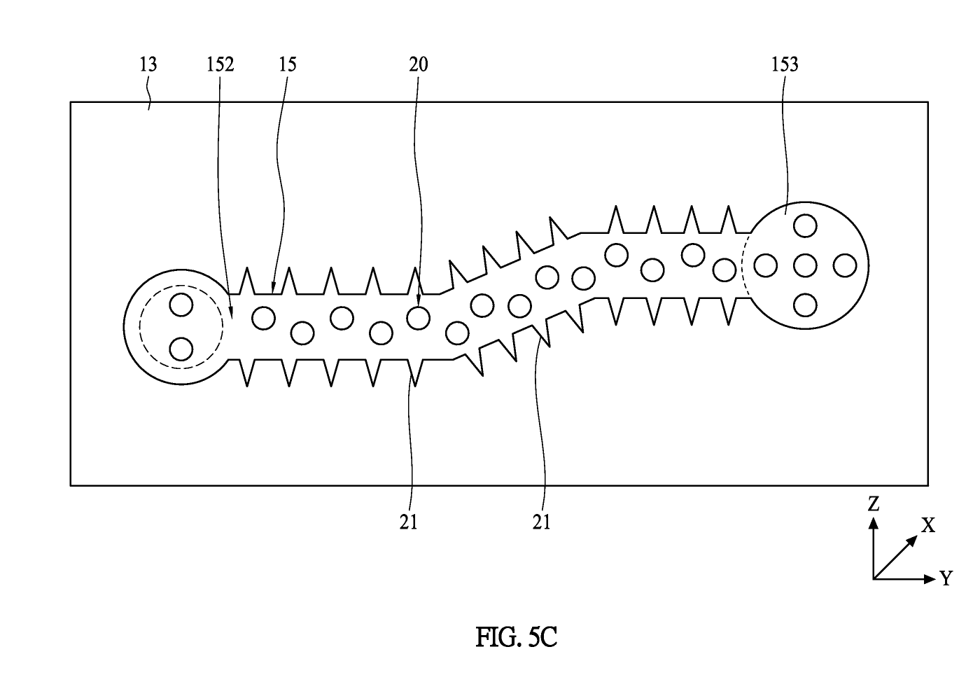

FIG. 5A to FIG. 5C show top views of the semiconductor structure according to the fifth to the seventh embodiments of the present invention. For simplicity, the bump 30 and the insulating layer 16 for covering the dielectric layer 13 and the wiring 15 are not shown in FIG. 5A to FIG. 5C. As shown in FIG. 5A to FIG. 5C, the edge of the wiring 15 further includes a plurality of protruding portions 21. The shape of the protruding portion 21 is, but not limited to, an arc, a wave, a square, a trapezoid, a saw-tooth shape, etc. The total area of the protruding portions 21 is from 5% to 30% of the surface area of the wiring 15. Since the protruding portions 21 can increase the contact area between the wiring 15 and the insulating layer 16 or the dielectric layer 13, and the increase in the contact area enhances the bonding strength between the wiring 15 and the insulating layer 16 or the dielectric layer 13, the delamination between the wiring 15 and the insulating layer 16 or the dielectric layer 13 can be avoided. In addition, since the insulating layer 16 can fill into the space between the adjacent protruding portions 21, the insulating layer 16 and the wiring 15 form locking components meshing with each other so that the bonding strength between the wiring 15 and the insulating layer 16 is further enhanced. The ratio of the total area of the protruding portions 21 to the surface area of the wiring 15 can be defined according to the difference between the coefficients of thermal expansion of the wiring 15 and the insulating layer 16 or dielectric layer 13. The shape of the holes 20 and the shape of the protruding portions 21 can be in any combination according to the requirements, but not limited to that shown in FIG. 5A to FIG. 5C.

In the embodiments of the present invention, holes are formed on the wiring to increase the total contact area between the insulating layer and the wiring, and to reduce the degree of mismatch of the coefficients of thermal expansion therebetween so that the bonding strength between the wiring and the insulating layer can be enhanced, and delamination between the wiring and the insulating layer can be avoided. In addition, forming the protruding portions at the edge of the wiring can further increase the total contact area between the insulating layer and the wiring so as to further avoid delamination. The present invention can be also applied for increasing the bonding strength between the contact pad of the wiring and the bump so as to avoid the bump from peeling off from the contact pad.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a semiconductor substrate;
an insulating layer disposed on the semiconductor substrate; and
a plurality of wirings disposed between the semiconductor substrate and the insulating layer, wherein at least one wiring of the wirings includes a plurality of holes, and a total area of the holes is from 10% to 70% of a surface area of the at least one wiring.

2. The semiconductor structure of claim 1, wherein the insulating layer partially covers the at least one wiring, and a part of the insulating layer is disposed in the holes.

3. The semiconductor structure of claim 1, further comprises a dielectric layer disposed in between the semiconductor substrate and the wirings, the insulating layer contacts the dielectric layer through the holes.

4. The semiconductor structure of claim 1, wherein an edge of the at least one wiring further comprises a plurality of protruding portions.

5. The semiconductor structure of claim 4, wherein a total area of the protruding portions is from 5% to 30% of the surface area of the at least one wiring.

6. The semiconductor structure of claim 5, wherein a ratio of a total area of the protruding portions to the surface area of the at least one wiring is defined according to a difference between coefficients of thermal expansion of the insulating layer and the at least one wiring.

7. The semiconductor structure of claim 1, wherein the at least one wiring comprises a contact pad for a bump to be disposed thereon.

8. The semiconductor structure of claim 7, wherein the insulating layer partially exposes the contact pad.

9. The semiconductor structure of claim 8, wherein at least one of the holes is disposed at the contact pad.

10. The semiconductor structure of claim 1, wherein a ratio of the total area of the holes to the surface area of the at least one wiring is defined according to a difference between coefficients of thermal expansion of the insulating layer and the at least one wiring.

11. The semiconductor structure of claim 1, wherein the holes pass through the at least one wiring.

12. A semiconductor structure, comprising:
a semiconductor substrate;
a dielectric layer disposed on the semiconductor substrate;
a plurality of wirings disposed on the dielectric layer, wherein at least one wiring of the wirings includes a plurality of holes; and
an insulating layer disposed on the semiconductor substrate, and partially covering the wirings, wherein a part of the insulating layer is disposed in the holes and contacts the dielectric layer through the holes; wherein a total area of the holes is from 10% to 70% of a surface area of the at least one wiring.

13. The semiconductor structure of claim 12, wherein an edge of the at least one wiring further comprises a plurality of protruding portions.

14. The semiconductor structure of claim 13, wherein a total area of the protruding portions is from 5% to 30% of the surface area of the at least one wiring.

15. The semiconductor structure of claim 14, wherein a ratio of the total area of the protruding portions to the surface area of the at least one wiring is defined according to a difference between coefficients of thermal expansion of the insulating layer and the at least one wiring.

16. The semiconductor structure of claim 12, wherein the at least one wiring comprises a contact pad for a bump to be disposed thereon.

17. The semiconductor structure of claim 16, wherein the insulating layer partially exposes the contact pad.

18. The semiconductor structure of claim 17, wherein at least one of the holes is disposed at the contact pad.

19. The semiconductor structure of claim 12, wherein a ratio of the total area of the holes to the surface area of the at least one wiring is defined according to a difference between coefficients of thermal expansion of the insulating layer and the at least one wiring.
